(19) United States
(12) Patent Application Publication
(10) Pub. No.: US 2012/0158330 A1
(43) Pub. Date: Jun. 21, 2012

(54) MONITORING SYSTEM FOR LITHIUM ION SECONDARY BATTERY AND MONITORING METHOD THEREOF

(75) Inventor: Kazuhiro Araki, Wako-shi (JP)

(73) Assignee: HONDA MOTOR CO., LTD, Tokyo (JP)

(21) Appl. No.: 13/384,194

(22) PCT Filed: Jul. 14, 2010
(86) PCT No.: PCT/JP2010/061906

§ 371 Date: Mar. 12, 2012

(30) Foreign Application Priority Data
Jul. 17, 2009 (JP) 2009-168924

(51) Int. Cl. G01R 31/36

(52) U.S. Cl. 702/63

(57) ABSTRACT

A monitoring system for a lithium ion secondary battery which detects deterioration of the lithium ion secondary battery accurately is provided. The monitoring system for a lithium ion secondary battery (1) for monitoring a state of the lithium ion secondary battery (2) that comprises: a control unit (3); a voltage detection unit which detects a terminal voltage of a battery unit (20) of one or a plurality of the lithium ion secondary battery/batteries (2); a calculation unit for an evaluation value change (5) which calculates a voltage change per unit time using the terminal voltage detected by the voltage detection unit (4) as the evaluation value change, or calculates an SOC using the terminal voltage detected by the voltage detection unit (4) and calculates an SOC change per unit time as the evaluation value change; and a determination unit (31) at the control unit (3) which determines deterioration of the battery unit (20) by comparing the evaluation value change calculated above with a reference evaluation value change under the predetermined condition.

### TECHNICAL FIELD

The present invention relates to a monitoring system to monitor a state of a lithium ion secondary battery and a monitoring method thereof.

### BACKGROUND ART

Lithium ion secondary batteries are used for various applications such as portable electronic devices such as cellular phones, portable audio players and notebook computers, since they have an excellent repeatable rechargeability and high energy density. Recently, there have been a growing number of researches to utilize lithium ion secondary batteries as onboard batteries for vehicles such as hybrid vehicles, plug-in hybrid vehicles, electric bicycles, electric motorcycles, electric forklifts and automatic guided vehicles, and as batteries for system interconnection to operate with interconnection with electric power system.

Until now, improvement of lithium ion secondary battery has been aimed at developing higher electricity capacity and higher output power, such as Patent Literature 1. Patent Literature 1 discloses a lithium ion secondary battery having a cathode formed on both sides of collector foil with a cathode mixture including a lithium transition metal composite oxide; an anode formed on both sides of collector foil with an anode mixture including anode active materials which absorb and release lithium; and a nonaqueous electrolyte including a lithium salt, wherein the anode mixture is a mixture of graphite, amorphous carbon material and binder, and a ratio of graphite to the sum of graphite and amorphous carbon material in the mixture is 20 to 80 wt %. Further, the amorphous carbon material described above is associated with a non-graphitizable carbon in the present invention.

Furthermore, Patent Literature 1 discloses a density ratio of an anode mixture including graphite, amorphous carbon material and binder ρ_{G}ρ_{A}/[ρ_{G}(1−x)+ρ_{A}x] is 0.55 to 0.70 (wherein ρ_{G}=true density of graphite; ρ_{A}=true density of amorphous carbon material; and x=ratio of graphite, wherein 0.2≦x≦0.8).

However, in these improved lithium ion secondary batteries aiming at higher electricity capacity and higher output power, deterioration is inevitable after charge and discharge cycles are repeated. This deterioration is caused by the reduction film generated on the surface of the anode after repeated charge and discharge cycles. Since the reduction film has a high resistance, the same charging electricity amount as that of undeteriorated state may not be allowed. As a result, the deteriorated lithium ion secondary batteries have a lowered electricity capacity and a lowered output, therefore, their original performances cannot be maintained.

Therefore, deterioration monitoring devices for lithium ion secondary batteries have been proposed, for example, in Patent Literatures 2 and 3.

Patent literature 2 discloses a battery monitoring device that monitors states of a secondary battery block, wherein the secondary battery block is composed of a plurality of parallel cell blocks connected in series, and the parallel cell blocks are composed of a plurality of parallel connected cells. The battery monitoring device includes: a voltage detection unit that detects a voltage of each of the parallel cell blocks; a current detection unit that detects a turning on current of the secondary battery block; a processing unit that calculates a voltage change of each of the parallel cell blocks before and after turning on the electricity in the secondary battery block based on the detected voltage by the voltage detection unit, as well as calculates a current-voltage change of each of the parallel cell blocks before and after turning on the electricity in the secondary battery block based on the detected current by the current detection unit, and calculates a direct current internal resistance based on the calculated voltage change and current-voltage change; and a determination unit that determines a disorder of the cells based on the calculated direct current internal resistance. The cells described above are associated with the lithium ion secondary batteries in the present invention, and the battery monitoring device is associated with the monitoring system for a lithium ion secondary battery in the present invention.

Further, Patent literature 2 describes that the determination unit calculates the ratio of the maximum value to the minimum value of the calculated direct current internal resistance of each of the parallel cell blocks, and determines the cells to be in disorder when the ratio of cells exceeds the predetermined set value.

Patent literature 3 describes a display device for deep charge and discharge including: a complementary charge unit which supplies an external power source to a secondary battery in a deep discharged state that is equipped in a built-in charger in an electronic equipment; and a display unit for a voltage state including a voltage detection unit that detects a voltage state of the secondary battery and controls the display of the voltage state of the secondary battery, and a display unit that displays the voltage state of the secondary battery that is equipped in the charger which is connected with the external power source.

Patent literature 3 also describes that when a voltage of the secondary battery does not reach the desired voltage even after the set time, in order to ensure the safety, a time measure and control unit generates a control signal toward a voltage detection unit and a complementary charge circuit unit to shut down ongoing function of charge and display, and to display an alarm to be out of order. The secondary batteries described above are associated with the lithium ion secondary batteries in the present invention.

### CITATION LIST

### Patent Literatures

Patent Literature 1: JP 2007-335360 (A)

Patent Literature 2: JP 2006-138750 (A)

Patent Literature 3: JP 2003-264937 (A)

There is a general need of secondary batteries not limiting to an anode material to detect their deteriorations and disorders, and to replace them with fresh batteries on the optimal timing.

Although, Patent Literature 1 aims at developing higher electricity capacity and higher output power lithium ion secondary batteries by balancing input to output by unit of using the specific ratio of graphite and amorphous carbon material to be of 20:80 to 80:20, and the specific range of the density ratio of the anode mixture including graphite, amorphous carbon material and binder to be of 0.55 to 0.70. Since the lithium ion secondary batteries described in Patent Literature 1 has no function to detect deterioration or disorder, no deterioration or a disorder is detected.

Further, Patent literature 2 discloses a battery monitoring device which detects disorders of the cell caused by either cell removal on account of broken wire, cell deterioration on account of increased internal resistance or safety element operation for the cell that gives no permission to charge the cell by safety system equipped in the cell. However, since Patent literature 2 describes the device to detect disorders of the cell including: detecting the voltage value or the current value of the cell before and after turning on the electricity (before and after discharging) or before and after turning off the electricity due to the full charge; and calculating with the specific formula, it is impossible to detect disorders of the cell in portable electronic devices, hybrid vehicles or the like until turning on the electricity at their startup or until turning off the electricity after full charging of the cell. In this case, immediately after turning on the power source to startup the portable electronic devices, hybrid vehicles or the like, disorders of the cell are detected. Therefore, facing tough situations to replace the secondary battery on the worst timing are supposed to be inevitable.

Moreover, Patent literature 3 discloses the display device for deep charge and discharge, and discloses that when a voltage of the secondary battery does not reach the desired voltage even after the set time, in order to ensure the health, a time measure and control unit only generates a control signal toward a voltage detection unit and a complementary charge circuit unit to shut down ongoing function of charge and display, and to display an alarm to be out of order. No determination on whether the secondary battery is deteriorated or not is confirmed in practice. Further, how to raise the voltage within the set time varies depending on various conditions such as a current value, a temperature or the like. Therefore, no accurate detection of deteriorations is allowed under the setting voltages which cover all the above conditions.

The present invention, conceived to address the conventional problems, has an objective to provide a monitoring system for a lithium ion secondary battery and a monitoring method for a lithium ion secondary battery which enable accurate detection of deteriorations of lithium ion secondary battery.

### SUMMARY OF INVENTION

(1) A monitoring system for a lithium ion secondary battery according to the present invention that comprises: a cathode including a lithium transition metal composite oxide; an anode including non-graphitizable carbon and graphite as anode active materials which absorb and release lithium; and an electrolyte which is filled between the cathode and the anode containing at least one lithium salt, the monitoring system comprising: a control unit for monitoring a state of the lithium ion secondary battery; a voltage detection unit which detects a terminal voltage of a battery unit of one or a plurality of the lithium ion secondary battery/batteries; a calculation unit for an evaluation value change which calculates a voltage change per unit time using the terminal voltage detected by the voltage detection unit as the evaluation value change, or calculates an SOC using the terminal voltage detected by the voltage detection unit and calculates an SOC change per unit time as the evaluation value change; and a determination unit of the control unit which determines that the battery unit is deteriorated by comparing the evaluation value change calculated above with a reference evaluation value change under the predetermined condition.

With respect to the lithium ion secondary battery having the above mentioned structure, the deterioration caused by repeatedly charge and discharge cycles makes the electric potential of the anode after charging lowered. As the cycles go on, graphite having high charge electricity capacity per voltage change of electric potential contributes to the charging gradually. Therefore, since the lowering of the electric potential (voltage) of the anode per unit time decreases, the heightening of the voltage of the secondary battery per unit time also decreases.

A monitoring system for a lithium ion secondary battery according to the present invention provides accurate detection of the battery unit to be deteriorated or not, since the battery unit is determined by the determination unit of the control unit by comparing the evaluation value change calculated by the calculation unit for an evaluation value change with a reference evaluation value change under the predetermined condition.

(2) It is preferable that the predetermined condition comprises at least one of a member selected from a current value during charging, a temperature during charging, a voltage value during charging and an SOC.

In this manner, since the reference evaluation value change which is the reference at the time when determination is made by the determination unit of the control unit is set more accurately, a monitoring system for a lithium ion secondary battery according to the present invention provides more accurate determination of the deterioration of the lithium ion secondary battery by comparing the evaluation value change with a reference evaluation value change.

(3) It is preferable that the battery unit is determined to be deteriorated by the determination unit: if the evaluation value change is within a first specific range of the reference evaluation value change for the battery unit being deteriorated; if the evaluation value change is outside of a second specific range of the reference evaluation value change for the battery unit for the battery unit being undeteriorated;

if the evaluation value change does not reach a first specific value of the reference evaluation value change for the battery unit being undeteriorated; or if the evaluation value change reaches a second specific value of the reference evaluation value change for the battery unit being deteriorated.

In this manner, since the relationship between the evaluation value change and the reference evaluation value change is clear, a monitoring system for a lithium ion secondary battery according to the present invention provides further more accurate determination of the deterioration of the lithium ion secondary battery.

(4) A monitoring method for a lithium ion secondary battery according to the present invention using a monitoring system for a lithium ion secondary battery that comprises: a cathode including a lithium transition metal composite oxide; an anode including non-graphitizable carbon and graphite as anode active materials which absorb and release lithium; and an electrolyte which is filled between the cathode and the anode including at least one lithium salt, wherein the monitoring method including: a control unit for monitoring a state of the lithium ion secondary battery; a voltage detection step of detecting a terminal voltage of a battery unit of one or a plurality of the lithium ion secondary battery/batteries; a calculation step for an evaluation value change of calculating a voltage change per unit time using the terminal voltage detected in the voltage detecting step as the evaluation value change, or calculating an SOC using the terminal voltage detected in the voltage detecting step and calculating an SOC change per unit time as the evaluation value change; and a determination step at the control unit of determinating whether the battery unit is deteriorated or not by comparing the evaluation value change calculated in the calculation step for an evaluation value change with a reference evaluation value change under the predetermined condition.

A monitoring method for a lithium ion secondary battery according to the present invention provides accurate detection of the battery unit to be deteriorated or not, since the battery unit is determined in the determination step at the control unit by comparing the evaluation value change calculated in the calculation step for an evaluation value change with a reference evaluation value change under the predetermined condition.

(5) It is preferable that the predetermined condition comprises at least one of a member from selected from a current value during charging, a temperature during charging, a voltage value during charging and an SOC.

In this manner, since the reference evaluation value change which is the reference at the time when determination is made in the determination step at the control unit is set more accurately, a monitoring method for a lithium ion secondary battery according to the present invention provides more accurate determination of the deterioration of the lithium ion secondary battery by comparing the evaluation value change with a reference evaluation value change.

(6) It is preferable that in the determination step at the control unit, the battery unit is determined to be deteriorated when the evaluation value change belongs to at least one case selected from the group consisting of: if the evaluation value change is within a first specific range of the reference evaluation value change for the battery unit being deteriorated; if the evaluation value change is outside of a second specific range of the reference evaluation value change for the battery unit being undeteriorated; if the evaluation value change does not reach a first specific value of the reference evaluation value change for the battery unit being undeteriorated; and if the evaluation value change reaches a second specific value of the reference evaluation value change for the battery unit being deteriorated.

In this manner, since the relationship between the evaluation value change and the reference evaluation value change is clear, a monitoring method for a lithium ion secondary battery according to the present invention provides further more accurate determination of the deterioration of the lithium ion secondary battery.

### Advantageous Effects of Invention

A monitoring system for a lithium ion secondary battery according to the present invention provides accurate detection of deterioration of the lithium ion secondary battery, since the system comprises a determination unit which determines the deterioration by comparing the evaluation value change with a reference evaluation value change under the predetermined condition. The evaluation value change is a voltage change per unit time or an SOC change per unit time which is calculated by the calculation unit for an evaluation value change from the terminal voltage detected by the voltage detection unit.

A monitoring method for a lithium ion secondary battery according to the present invention provides accurate detection of deterioration of the lithium ion secondary battery, since the method comprises a determination step of determinating the deterioration by comparing the evaluation value change with a reference evaluation value change under the predetermined condition. The evaluation value change is a voltage change per unit time or an SOC change per unit time which is calculated in the calculation step for an evaluation value change from the terminal voltage detected in the voltage detecting step.

### BRIEF DESCRIPTION OF DRAWINGS

FIG. 1 is a block diagram showing a structure of a monitoring system for a lithium ion secondary battery according to the present invention;

FIG. 2 is a diagram showing a structure of a power generation element for lithium ion secondary battery used in the present invention;

FIG. 3 is a sectional diagram showing a structure of a lithium ion secondary battery used in the present invention;

FIG. 4 is a diagram showing relationship between a charging electricity amount [mAh/g] and an anode potential (vs. Li metal) [V] of mixture of non-graphitizable carbon and graphite, of graphite, and of non-graphitizable carbon;

FIG. 5 is a diagram showing relationship between charging time and cell voltage (differential voltage between the anode and cathode) [V] of mixture of non-graphitizable carbon and graphite, and of graphite;

FIGS. 6(a) to (d) are diagrams showing relationship between the reference evaluation value change and an evaluation value change;

FIG. 7 is a flowchart showing steps of a monitoring method for a lithium ion secondary battery according to the present invention;

FIG. 8 is a flowchart showing an embodiment of a specific operation of a monitoring method for a lithium ion secondary battery according to the present invention; and

FIG. 9 is a flowchart showing another embodiment of a specific operation of a monitoring method for a lithium ion secondary battery according to the present invention.

### DESCRIPTION OF EMBODIMENTS

Here, a monitoring system for a lithium ion secondary battery according to the present invention and a monitoring method for a lithium ion secondary battery according to the present invention are described in detail below by referring to drawings as appropriate.

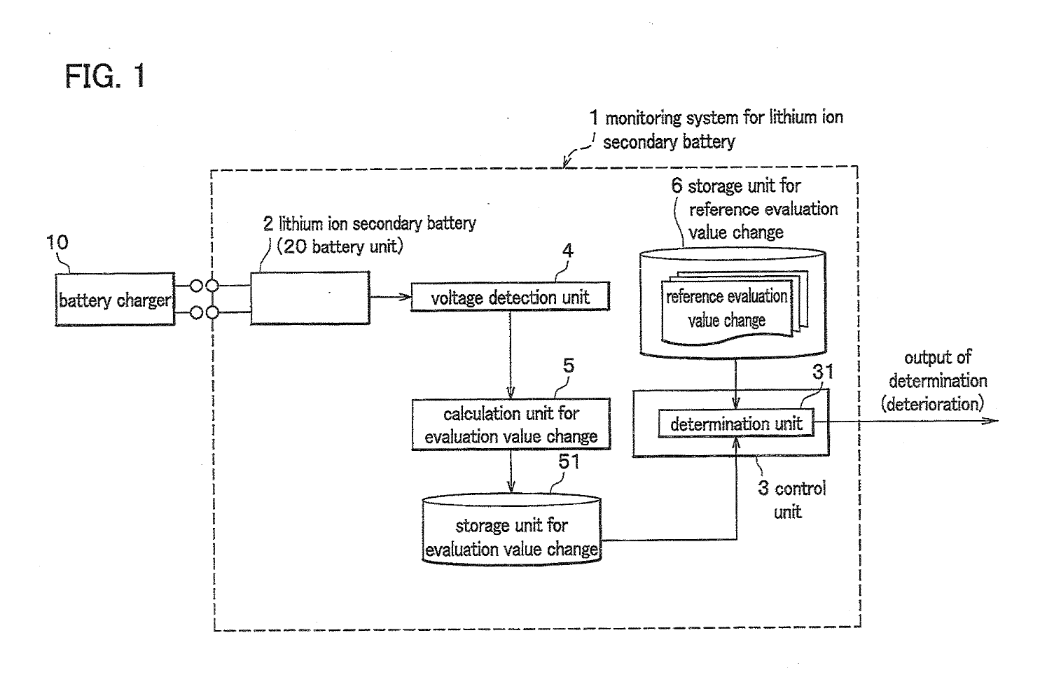

At first, a monitoring system for a lithium ion secondary battery according to the present invention is described by referring to FIG. 1. As shown in FIG. 1, a monitoring system for a lithium ion secondary battery 1 includes a control unit 3 for monitoring a state of the lithium ion secondary battery 2; a voltage detection unit 4; a calculation unit for an evaluation value change 5; a storage unit for a reference evaluation value change 6; and a determination unit 31. The system monitors the charging state of the lithium ion secondary battery 2 (battery unit 20) which is charged by being connected to a battery charger 10.

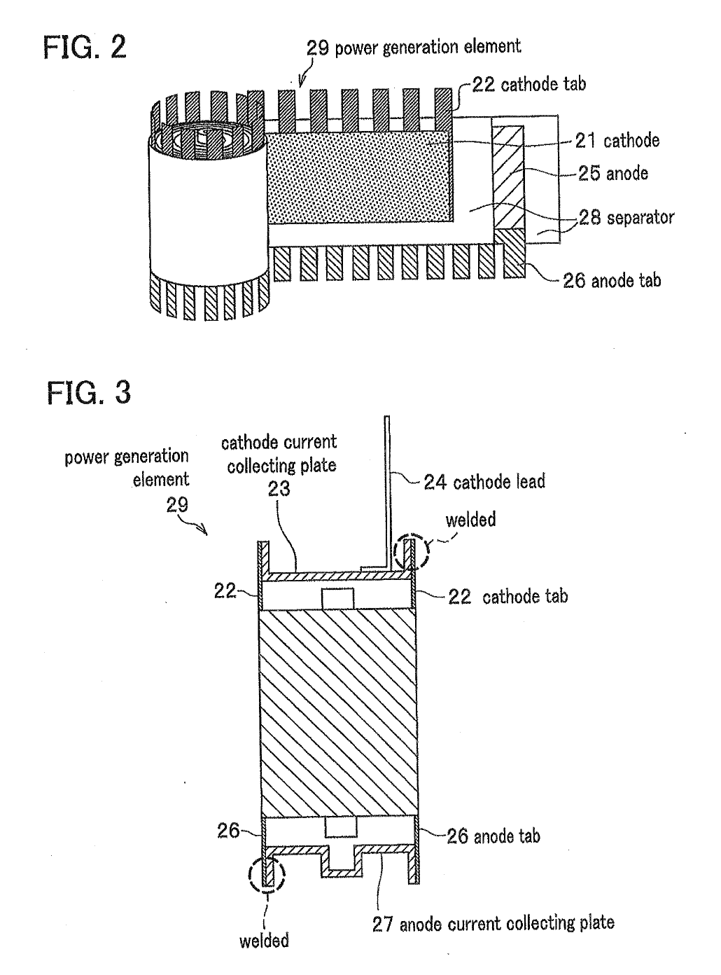

Here, prior to describing a monitoring system for a lithium ion secondary battery 1 in detail, a lithium ion secondary battery 2 used in the present invention is described. As shown in FIG. 2, a lithium ion secondary battery 2 used in the present invention is formed as follows. First, each of a cathode 21, an anode 25, and a separator 28 is formed in a long strip shape. The separator 28 includes an electrolyte between the cathode 21 and the anode 25. The cathode 21, separator and the anode 25 are slathed in this order. Next, a set of these strips is wound in coil to form a cylindrical power generation element 29 in layer state. Then, the power generation element is enclosed in a cylindrical battery can (not shown) to form a lithium ion secondary battery. Further, the shape of the lithium ion secondary battery 2 is not limited to a cylindrical shape, but a prismatic shape may be formed as well.

The cathode 21 is formed by applying a mixture of a cathode active material, a conducting agent and a binder dispersed in a solvent onto an electric conductor such as aluminum foil. Further, as shown in FIG. 3, the cathode 21 equips a cathode tab 22 on the upper side of the electric conductor, to join with a cathode current collecting plate 23 by welding or the like. The cathode tab 22 has a plurality of join strips at the coil end portion of the power generation element 29.

The cathode 21 may comprise a lithium transition metal composite oxide as a cathode active material. The cathode active material includes, for example, lithium manganese composite oxide LiₓMn₂O₄ or LiₓMnO₂), lithium nickel composite oxide (LiₓNiO₂), lithium cobalt composite oxide (LiₓCoO₂), lithium nickel cobalt composite oxide (LiNi_{1-y}Co_{y}O₂), lithium manganese cobalt composite oxide (LiMn_{y}Co_{1-y}O₂), lithium manganese nickel composite oxide having a spinel structure (LiₓMn_{2-y}Ni_{y}O₄), lithium phosphate having an olivine structure (LiₓFePO₄, LiₓFe_{1-y}Mn_{y}PO₄, LiₓCoPO₄), LiNiCoAlO₂, Li₂MnO₃, Li_{2-x-y}FeₓMn_{y}O₂, Li₂Fe₁₋ₓMnₓSiO₄, LiNi_{1/3}Mn_{1/3}CO_{1/3}O₂ and the like. Each of them may be used by itself or a mixture of them may be used. (wherein x, y in the above mentioned compounds is preferably in a range from more than 0 to no more than 1).

The conducting agent includes acetylene black, carbon black, ketjen black, graphite, carbon fiber and the like. The binder includes polyvinylidene difluoride (PVdF), polytetrafluoroethylene (PTFE), fluoro rubber and the like. The solvent includes N-methyl-2-pyrrolidone (NMP), water and the like.

The anode 25 is formed by applying a mixture of an anode active material, a conducting agent and a binder dispersed in a solvent onto an electric conductor such as copper foil. Further, as shown in FIG. 3, the anode 25 equips an anode tab 26 on the lower side of the electric conductor, to join with an anode current collecting plate 27 by welding or the like. The anode tab 26 has a plurality of join strips at the coil end portion of the power generation element 29.

The anode 25 may comprise non-graphitizable carbon and graphite as anode active materials which absorb and release lithium. Non-graphitizable carbon (hard carbon) is a carbon material heat treated at 1000 to 1400° C. which is hard to be graphitized through a heat treatment. Even after this heat treatment at around 3000° C., no conversion from a turbostratic structure to a graphite structure occurs and as a result no development of graphite crystallite is observed. Such non-graphitizable carbon includes, for example, polyacene, non-graphitizable carbon having silicon and the like.

A conventionally known graphite (black lead) may be used. For example, graphite having synthetic graphite, mesophase graphite and natural graphite as base material may be used. The lower limit of a graphite content to a non-graphitizable carbon is preferably at least 15 mass %, more preferably at least 20 mass %. Within this range, the voltage detection unit 4 detects a voltage accurately even if the anode potential drops down to 0.15 V. On the other hand, the upper limit of a graphite content relative to a non-graphitizable carbon is preferably 40 mass %. There is a risk of lowering an energy density, since the content of an active material which is not utilized until a life span of the lithium ion secondary battery 2 after advanced deteriorations, that is, a graphite is contained more. If the content of a graphite to a non-graphitizable carbon is no more than 40 mass %, a lowering rate of the energy density is suppressed below 10 mass %.

The electrolyte may comprise at least an inorganic or organic lithium salt, be prepared by dissolving the salt in nonaqueous solvent such as an organic electrolyte solution or an ionic liquid (ordinary temperature molten salt), and be allowed to be filled between the cathode 21 and the anode 25 by the impregnation or the like into the separator 28. Such electrolyte includes, for example, LiClO₄, LiPF₆, LiBF₄, LiBOB, LiTFSI, LiAsF₆, LiCF₃SO₃, LiN(CF₃SO₂)₂, LiN(CF₃CF₂SO₂)₂, LiN(CF₃SO₂) (C₄F₉SO₂), LiC(CF₃SO₂)₃ and the like. Each of them may be used by itself or a mixture of them may be used in combination. Further, the electrolyte may comprise a solvent or an additive if necessary which is commonly used.

The organic electrolyte solution includes cyclic esters such as ethylene carbonate, vinylene carbonate, propylene carbonate, butylene carbonate, and γ-butyrolactone; chain esters used as low-boiling point solvents such as diethyl carbonate, ethyl methyl carbonate, dimethyl carbonate, methyl ethyl carbonate. Each of them may be used by itself or a mixture of them may be used in combination.

The ionic liquid includes ionic liquids based on imidazolium cation or ionic liquids based on acyclic or cyclic quaternary ammonium cation.

The ionic liquids based on imidazolium cation include ionic liquids based on dialkyl imidazolium cation such as 1,3-dimethyl imidazolium salt, 1-ethyl-3-methyl imidazolium salt, 1-methyl-3-ethyl imidazolium salt, 1-methyl-3-butyl imidazolium salt, 1-butyl-3-methyl imidazolium salt; and ionic liquids based on trialkyl imidazolium cation such as 1,2,3-trimethyl imidazolium salt, 1,2-dimethyl-3-ethyl imidazolium salt, 1,2-dimethyl-3-propyl imidazolium salt, 1-butyl-2,3-dimethyl imidazolium salt.

The ionic liquids based on acyclic or cyclic quaternary ammonium cation include trimethylethylammonium salt, trimethylpropylammonium salt, trimethylhexylammonium salt, and ionic liquids based on tetraalkylammonium cation such as tetrapenthylammonium salt; and liquids based on alkylpyridinium cation such as N-methylpyridinium salt, N-ethylpyridinium salt, N-propylpyridinium salt, N-butylpyridinium salt, 1-ethyl-2-methylpyridinium salt, 1-butyl-4-methylpyridinium salt, 1-butyl-2,4-dimethylpyridinium. Further, the ionic liquids based on cyclic quaternary ammonium cation include ionic also liquids based on such as pyrazolium cation, pyrrolidinium cation and piperidinium cation.

The separator 28 may include, for example, porous film or nonwoven fabric made of polyolefin synthetic resins such as polyethylene, polypropylene and polyvinylidene fluoride; and cellulose.

As shown in FIG. 2, the power generation element 29 which is composed of the above described elements is formed in a cylindrical shape. Then, as shown in the sectional diagram FIG. 3, at the cathode 21, the cathode tab 22 and the cathode current collecting plate 23 are jointed by welding. Further, to the cathode current collecting plate 23, the cathode lead 24 is jointed by welding. On the other hand, as shown in the sectional diagram FIG. 3, at the anode 25 side, the anode tab 26 and the anode current collecting plate 27 are jointed by welding. After jointing the cathode current collecting plate 23 to the cathode 21 and the anode current collecting plate 27 to the anode 25 respectively, the anode current collecting plate 27 is placed into abutting contact with the bottom section in the cylindrical battery can having the bottom section (not shown). Thereafter, the bottom section of the battery can and the anode current collecting plate 27 are jointed by projection welding. Then, into the power generation element 29, a nonaqueous solvent solution is poured. Here, the nonaqueous solvent solution is prepared by dissolving the above mentioned electrolyte. Thereafter, the opening section in the cylindrical battery can is covered with a can lid and then both of the opening section and the can lid are joint welded and encapsulated. In this way, the lithium ion secondary battery 2 according to the present invention is produced

In addition, the battery unit 20 may be prepared by being connected one or a plurality of such lithium ion secondary battery/batteries 2 in series or in parallel and by placing it/them into the designated casing.

In the lithium ion secondary battery 2 described above, the active materials for the cathode 21 and anode 25 utilize lithium/lithium ion. Thus, impurities such as CH (OLi)₃ or Li₂CO₃ are formed after repeated charge and discharge cycles in a similar way to the conventionally known lithium ion secondary battery. Therefore, the original potential is not allowed to be obtained by discharging. Although, the same amount of charging electricity as the last charging is allowed to be obtained by recharging the lithium ion secondary battery at this state. Since, impurities are also formed during this recharging, the repeated charge and discharge cycles make the potentials after recharging and discharging lower. Accordingly, the charging electricity amount after recharging decreased substantially.

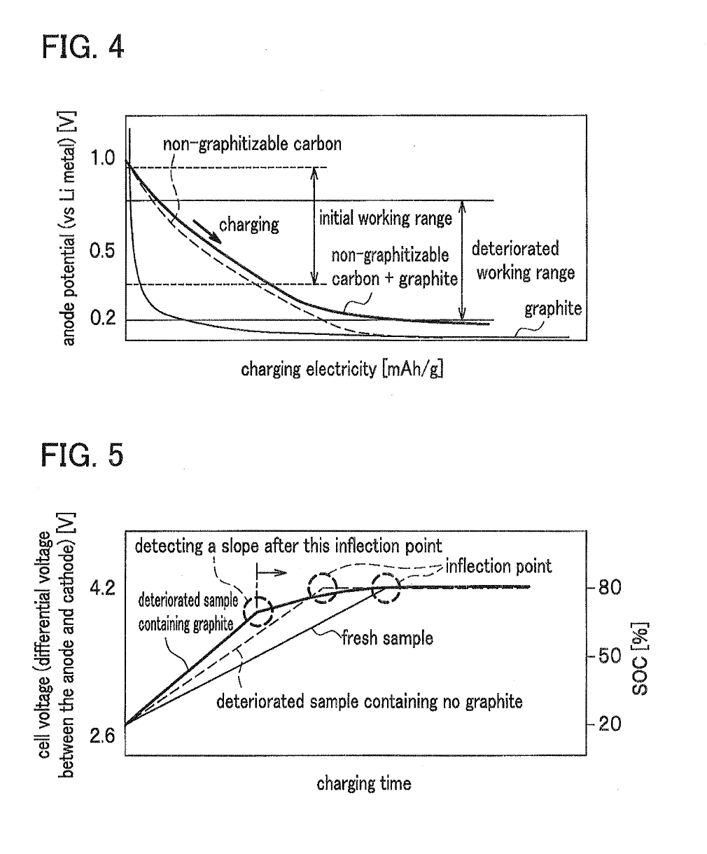

However, a lithium ion secondary battery 2 used in the present invention has two features described below, since a non-graphitizable carbon and a graphite are utilized for an anodes 25. (1) Firstly, the relationship between a charging electricity amount [mAh/g] and an anode 25 potential (vs. Li metal) [V] of the lithium ion secondary battery 2 is described with reference to FIG. 4. As shown in FIG. 4, the non-graphitizable carbon has a characteristic that when the potential is about 0.6 V or below, the charging electricity amount increases linearly and gradually along with the lowering of the potential. On the other hand, the graphite has a characteristic that until the anode potential reaches around 0.2 V, the anode potential has a little effect on the charging electricity amount, and when the anode potential is below 0.2 V, rapid charging occurs and the charging electricity amount increase rapidly along with the lowering of the anode potential. Therefore, the lithium ion secondary battery 2 using a mixture of non-graphitizable carbon and graphite for the anode 25 has a characteristic of both that until the anode potential is lowered to around 0.2 V, the charging electricity amount increases gradually along with the lowering of the anode potential, and when the anode potential is below 0.2 V, the charging electricity amount increases rapidly along with the lowering of the anode potential.

Accordingly, in case of the initial use (fresh) lithium ion secondary battery 2, since the lithium ion secondary battery 2 has a high anode 25 potential after fully charging, the charging electricity amount increases gradually along with the lowering of the potential during charging (see “initial working range” in FIG. 4). On the other hand, in case of a deteriorated lithium ion secondary battery caused by repeatedly charge and discharge cycles, since the deteriorated lithium ion secondary battery 2 has a lowered anode 25 potential after charging, when the potential reaches around 0.2 V during charging, the deteriorated lithium ion secondary battery 2 has a characteristic that the charging electricity amount increases rapidly along with the lowering of the potential (see “deteriorated working range” in FIG. 4).

(2) Secondly, the relationship between charging time and cell voltage (differential voltage between the anode and cathode) [V] of the lithium ion secondary battery 2 is described with reference to FIG. 5. In general, the secondary battery is charged with a constant current until the cell voltage reaches a certain value. After the cell voltage reaches a certain value, the batteries are charged with a constant voltage for a certain time. Accordingly, under these charging conditions, since the fresh sample of the lithium ion secondary battery 2 has a high working range (see FIG. 4), the cell voltage increases linearly with the charging time (charging amount) as shown in FIG. 5 (see “fresh sample” in FIG. 5). When deterioration caused by repeatedly charge and discharge cycles begins to occur, impurities are formed on the surface of the anode 25, therefore, the surface resistance of the anode 25 increases. Higher the resistance becomes, higher the cell voltage (V=RI) at the identical charging time. Therefore, the inclination of the cell voltage per unit charging time becomes greater. When the deterioration progresses further, the anode 25 potential decreases and is shifted into the area of a “deteriorated working range” shown in FIG. 4. In this manner, in the area where the anode 25 potential is low, the increase rate of cell voltage to the increase of charging electricity amount slowdowns at around 4.2 V (i.e., the inclination becomes smaller), and the relationship rises in a gentle curve after the inflection point or later which appears at around the 4.2 V (more precisely around 4.15 V). In this connection, when the lithium ion secondary battery containing no graphite is deteriorated (see “deteriorated sample containing no graphite” in FIG. 5), the cell voltage rises to around 4.2 V linearly with a greater inclination than that of the “fresh sample”.

According to the characteristics described above in (1) and (2), determination on whether the lithium ion secondary battery is deteriorated or not is made as follows. Firstly, the determination is performed by detecting the terminal voltage of the battery unit 20 (the lithium ion secondary battery 2) during charging. Secondly, the determination is performed by calculating the cell voltage. Thirdly, the determination is performed by finding the inflection point where the rising value of the cell voltage changes during the cell voltage at the beginning of charging (2.6 V) to the cell voltage at the full charging (4.2 V). And finally, the determination is performed by comparing the voltage change of the cell voltage per unit time (the evaluation value change) before and after the inflection point with the evaluation value change to be the reference (the reference evaluation value change) under the predetermined condition.

Further, graph shown in FIG. 5 illustrates that the inclination after the inflection point which indicates the deterioration (i.e., the evaluation value change (the voltage change of the cell voltage per unit time)) is smaller than the inclination (the evaluation value change) of the fresh sample. Furthermore, the inclination (the evaluation value change) of the fresh sample is found to be smaller than the inclination (the evaluation value change) of the slightly deteriorated sample, and the inclination (the evaluation value change) of the slightly deteriorated sample is found to be smaller than the inclination (the evaluation value change) of the deteriorated sample before the inflection point.

That is, the following relationship of inclinations is observed. Namely, “the inclination (the evaluation value change) of the deteriorated lithium ion secondary battery after the inflection point<the inclination (the evaluation value change) of the fresh lithium ion secondary battery from the beginning of charging to the inflection point<the inclination (the evaluation value change) of the slightly deteriorated lithium ion secondary battery from the beginning of charging to the inflection point<the inclination (the evaluation value change) of the deteriorated lithium ion secondary battery before the inflection point” is observed. Thus, based on the above relationship, the evaluation value changes at and after the inflection point up to full charging (the cell voltage of 4.2 V) for the fresh and slightly deteriorated samples are not mistaken for the evaluation value changes at and after the inflection point of the deterioration. Therefore, a determination unit 31 at the control Unit 3 has no risk to misjudge the battery unit 20 to be deteriorated by comparing the evaluation value changes (the voltage changes of the cell voltage per unit time) at and after the inflection point up to full charging (the cell voltage of 4.2 V) for the fresh and slightly deteriorated samples with a reference evaluation value change (the reference voltage change per unit time) under the predetermined condition.

In the above description referring to FIG. 5, the relationship between charging time and cell voltage (differential voltage between the anode and cathode) [V] of the lithium ion secondary battery 2 is described. However, by replacing cell voltage (differential voltage between the anode and cathode) [V] with an SOC [%], it is described exactly the same. That is, by replacing the cell voltage of 2.6 V with, for example, SOC of 20%, and by replacing the cell voltage of 4.2 V with, for example, SOC of 80%, the relationship “the inclination (the evaluation value change (the SOC change per unit time)) of the deteriorated lithium ion secondary battery after the inflection point<the inclination (the evaluation value change) of the fresh lithium ion secondary battery from the beginning of charging to the inflection point<the inclination (the evaluation value change) of the slightly deteriorated lithium ion secondary battery from the beginning of charging to the inflection point<the inclination (the evaluation value change) of the deteriorated lithium ion secondary battery before the inflection point” is established in the same manner as the above. Thus, the deterioration of the lithium ion secondary battery can be detected accurately and with no risk of misjudgment.

Moreover, it should be understood that by detecting and determinating whether the cell voltage detected from the terminal voltage lowers below around 4.2 V or not, the evaluation value change (the voltage change per unit time or the SOC change per unit time) may be calculated when the cell voltage lowers below around 4.2 V, according to the above properties shown in (1) and (2). In this manner, even if the evaluation value change calculated by a calculation unit for an evaluation value change 5 is stored in a storage unit for an evaluation value change 51 described hereinafter, preferably the storage unit for an evaluation value change 51 not only has no need to memorize a huge amount of information, but also has an ability to reduce the electric power consumption.

As is described above, in order to enable the above mentioned determination, the monitoring system for a lithium ion secondary battery 1 according to the present invention includes: a control unit 3 for monitoring a state of the lithium ion secondary battery 2 (the battery unit 20); a voltage detection unit 4; a calculation unit for an evaluation value change 5; a storage unit for a reference evaluation value change 6; and a determination unit 31 (see FIG. 1)

The control unit 3 shown in FIG. 1 has a function as the determination unit 31 described hereinafter, and which includes ECU (electronic control unit) including CPU (central processing unit). The control unit 3 monitors the state of the lithium ion secondary battery 2 by executing programs stored in ROM (read only memory), HDD (hard disk drive) or the like (not shown).

The voltage detection unit 4 detects a terminal voltage of battery unit 20 including one or a plurality of the above mentioned lithium ion secondary batteries 2. The voltage detection unit 4 may use the previously known voltage meter which is able to detect the terminal voltage of the battery unit 20. Further, it is preferable not only to detect the terminal voltage of the battery unit 20 but also to measure the current value or temperature of the battery unit 20 at the same time with measuring devices which is able to measure its current value or temperature, since the measurement enables the calculation of an SOC more properly.

The calculation unit for an evaluation value change 5 calculates a voltage change per unit time as the evaluation value change using the terminal voltage detected by the voltage detection unit 4, or calculates an SOC using the terminal voltage detected by the voltage detection unit 4 and calculates an SOC change per unit time as the evaluation value change. The calculation unit for an evaluation value change 5 includes so called CPU and the like, which calculates the above mentioned evaluation value change by executing programs stored in ROM, HDD (not shown) or the like. Further, the calculation unit for an evaluation value change 5 may use the CPU at the control unit 3, also use another CPU which is separately installed from the control unit 3.

The evaluation value change calculated by a calculation unit for an evaluation value change 5 may be stored (memorized) in a storage unit for an evaluation value change 51 such as HDD and RAM (random access memory).

The determination unit 31 at the control unit 3 which determines whether the battery unit 20 is deteriorated or not by comparing the evaluation value change with a reference evaluation value change under the predetermined condition. Here, the evaluation value change is calculated by the calculation unit for an evaluation value change 5 and stored in the storage unit for an evaluation value change 51, and the reference evaluation value change under the predetermined condition is stored in the storage unit for a reference evaluation value change 6.

The predetermined condition comprises at least one of a current value during charging, a temperature during charging, a voltage value during charging and an SOC (State Of Charge). Further, a current value during charging is measured by an amperemeter (not shown) connecting to battery unit 20, a temperature during charging is measured by a thermometer (not shown) contacting with battery unit 20, a voltage value during charging is detected by the above mentioned voltage detection unit 4 and an SOC is obtained (measured) by measuring and calculating voltage, current and the like.

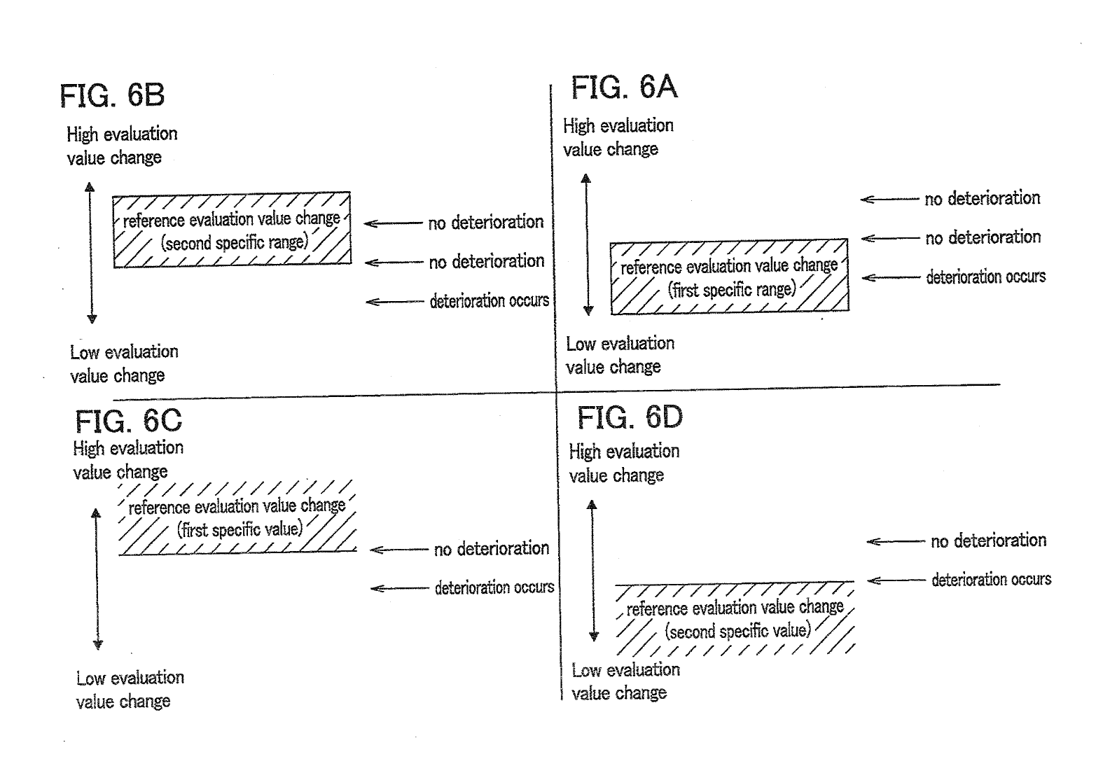

As shown in FIG. 6, in this determination unit 31, battery unit 20 (lithium ion secondary battery 2) is determined to be deteriorated when the evaluation value change belongs to at least one case selected from the group consisting either of the followings. Firstly, if the evaluation value change is within a first specific range of the reference evaluation value change for the battery unit being deteriorated (FIG. 6A). Secondly, if the evaluation value change is outside of a second specific range of the reference evaluation value change for the battery unit being undeteriorated (FIG. 6B). Thirdly, if the evaluation value change does not reach a first specific value of the reference evaluation value change for the battery unit being undeteriorated (FIG. 6C). Finally, if the evaluation value change reaches a second specific value of the reference evaluation value change for the battery unit being deteriorated (FIG. 6D). Accordingly, the storage unit for a reference evaluation value change 6 may store at least one data of the reference evaluation value change of cases shown in FIGS. 6(a) to (d).

In this manner, the reference evaluation value change under the predetermined condition may be stored in the storage unit for a reference evaluation value change 6 as described above. The storage unit for a reference evaluation value change 6 is constituted by HDD and ROM and the like. Further, FIG. 1 shows an embodiment using the storage unit that is separated from the storage unit for an evaluation value change 51 for convenience of explanation. However, of course HDD or ROM that is identical with the storage unit for an evaluation value change 51 may be used. The reference evaluation value change which is stored in the storage unit for a reference evaluation value change 6 is described specifically as follows.

Firstly, if the predetermined condition is a current value during charging, the battery is determined to be deteriorated when the evaluation value change is within a first specific range of the reference evaluation value change (FIG. 6A), ranging from 1 to 2 mV/10 seconds, for example, when a 1 C rate charging is performed. Secondly, if the predetermined condition is a current value during charging, the battery is determined to be deteriorated when the evaluation value change is outside of a second specific range of the reference evaluation value change (FIG. 6B), ranging from 3 to 4 mV/10 seconds, for example, when a 1 C rate charging is performed. Thirdly, if the predetermined condition is a current value during charging, the battery is determined to be deteriorated when the evaluation value change does not reach a first specific value of the reference evaluation value change (FIG. 6C) ranging 2.5 mV/10 seconds, for example, when a 1 C rate charging is performed. Finally, if the predetermined condition is a current value during charging, the battery is determined to be deteriorated when the evaluation value change reaches a second specific value of the reference evaluation value change (FIG. 6D), ranging 2.5 mV/10 seconds, for example, when a 1C rate charging is performed. Here, 1 C charge rate refers to a charging rate which completes in an hour.

Firstly, if the predetermined condition is a temperature during charging, the battery is determined to be deteriorated when the evaluation value change is within a first specific range of the reference evaluation value change (FIG. 6A), ranging from 1.5 to 2.5 mV/10 seconds, for, example, when the temperature of the battery unit 20 is 10° C. Secondly, if the predetermined condition is a temperature during charging, the battery is determined to be deteriorated when the evaluation value change is outside of a second specific range of the reference evaluation value change (FIG. 6B), ranging from 3.5 to 4.5 mV/10 seconds, for example, when the temperature of the battery unit 20 is 10° C. Thirdly, if the predetermined condition is a temperature during charging, the battery is determined to be deteriorated when the evaluation value change does not reach a first specific value of the reference evaluation value change (FIG. 6C), ranging 3 mV/10 seconds, for example, when the temperature of the battery unit 20 is 10° C. Finally, if the predetermined condition is a temperature during charging, the battery is determined to be deteriorated when the evaluation value change reaches a second specific value of the reference evaluation value change (FIG. 69), ranging 3 mV/10 seconds, for example, when the temperature of the battery unit 20 is 10° C.

Firstly, if the predetermined condition is a voltage value during charging, the battery is determined to be deteriorated when the evaluation value change is within a first specific range of the reference evaluation value change (FIG. 6A), ranging from 3 to 3.5 mV/10 seconds, for example, when the cell voltage is 4.1 V. Secondly, if the predetermined condition is a current value during charging, the battery is determined to be deteriorated when the evaluation value change is outside of a second specific range of the reference evaluation value change (FIG. 6B), ranging from 1 to 2 mV/10 seconds, for example, when the cell voltage is 4.1 V. Thirdly, if the predetermined condition is a current value during charging, the battery is determined to be deteriorated when the evaluation value change does not reach a first specific value of the reference evaluation value change (FIG. 6C), ranging 2.5 mV/10 seconds, for example, when the cell voltage is 4.1 V. Finally, if the predetermined condition is a current value during charging, the battery is determined to be deteriorated when the evaluation value change reaches a second specific value of the reference evaluation value change (FIG. 6D), ranging 2.5 mV/10 seconds, for example, when the cell voltage is 4.1 V.

Firstly, if the predetermined condition is an SOC, a first specific range, the battery is determined to be deteriorated when the evaluation value change is within a first specific range of the reference evaluation value change (FIG. 6A), ranging from 3 to 3.5 mV/10 seconds, for example, when the SOC is 80%. Secondly, if the predetermined condition is an SOC, the battery is determined to be deteriorated when the evaluation value change is outside of a second specific range of the reference evaluation value change (FIG. 6B), ranging from 1 to 2 mV/10 seconds, for example, when the SOC is 80%. Thirdly, if the predetermined condition is an SOC, the battery is determined to be deteriorated when the evaluation value change does not reach a first specific value of the reference evaluation value change (FIG. 6C), ranging 2.5 mV/10 seconds, for example, when the SOC is 80%. Finally, if the predetermined condition is an SOC, the battery is determined to be deteriorated when the evaluation value change reaches a second specific value of the reference evaluation value change (FIG. 6D), ranging 2.5 mV/10 seconds, for example, when the SOC is 80%.

Consequently, in FIG. 6A, the battery is determined to be deteriorated when the evaluation value change is within a first specific range. Therefore, when the evaluation value change is low and within the first specific range of reference evaluation value change in FIG. 6A, deterioration of the battery unit is determined to occur. On the other hand, when the evaluation value change is high and out of the first specific range, at least no deterioration of the battery unit is determined to occur.

In FIG. 6B, the battery is determined to be deteriorated when the evaluation value change is outside of a second specific range. Therefore, when the evaluation value change is low and out of the second specific range of the reference evaluation value change in FIG. 6B, deterioration is determined to occur. On the other hand, when the evaluation value change is high and within the second specific range, no deterioration is determined to occur.

In FIG. 6C, the battery is determined to be deteriorated when the evaluation value change does not reach a first specific value. Therefore, when the evaluation value change is low and does not reach the first specific value (i.e., lower than the first specific value) of the reference evaluation value change in FIG. 6C, deterioration of the battery unit is determined to occur. On the other hand, when the evaluation value change is high and reaches the first specific value (i.e., equal to or higher than the first specific value), no deterioration of the battery unit is determined to occur.

In FIG. 6D, the battery is determined to be deteriorated when the evaluation value change reaches a second specific value. Therefore, when the evaluation value change is low and reaches the second specific value (i.e., equal to or lower than the second specific value) of the reference evaluation value change in FIG. 6D, deterioration of the battery unit is determined to occur. On the other hand, when the evaluation value change is high and does not reach the second specific value (i.e., higher than the second specific value), at least no deterioration of the battery unit is determined to occur.

When the monitoring system for a lithium ion secondary battery 1 according to the present invention has determined a lithium ion secondary battery 2 to be deteriorated, signal to warn the deterioration is outputted to a warning device or a display panel which is not shown in FIG. 1, and the deterioration of the lithium ion secondary battery 2 is displayed in the warning device or the display panel.

As described above, the monitoring system for a lithium ion secondary battery 1 according to the present invention has been described. Here, a monitoring method for a lithium ion secondary battery using a monitoring system for a lithium ion secondary battery 1 according to the present invention is described in detail.

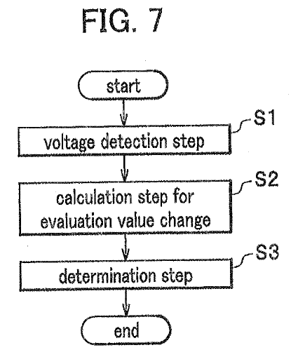

As shown in FIG. 7, the monitoring method for a lithium ion secondary battery according to the present invention includes the steps which are operated in that order: a voltage detection step (Step S1) of detecting terminal voltage of a battery unit 20 of one or a plurality of the lithium ion secondary battery/batteries 2; a calculation step for an evaluation value change (Step S2) of calculating voltage change per unit time using the terminal voltage detected in the voltage detecting step (Step S1) as the evaluation value change, or calculating an SOC using the terminal voltage detected in the voltage detecting step (Step S1) and calculating an SOC change per unit time as the evaluation value change; and a determination step (Step S3) at the control unit 3 of determinating whether the battery unit is deteriorated 20 by comparing the evaluation value change calculated in the calculation step for an evaluation value change (Step S2) with a reference evaluation value change under the predetermined condition.

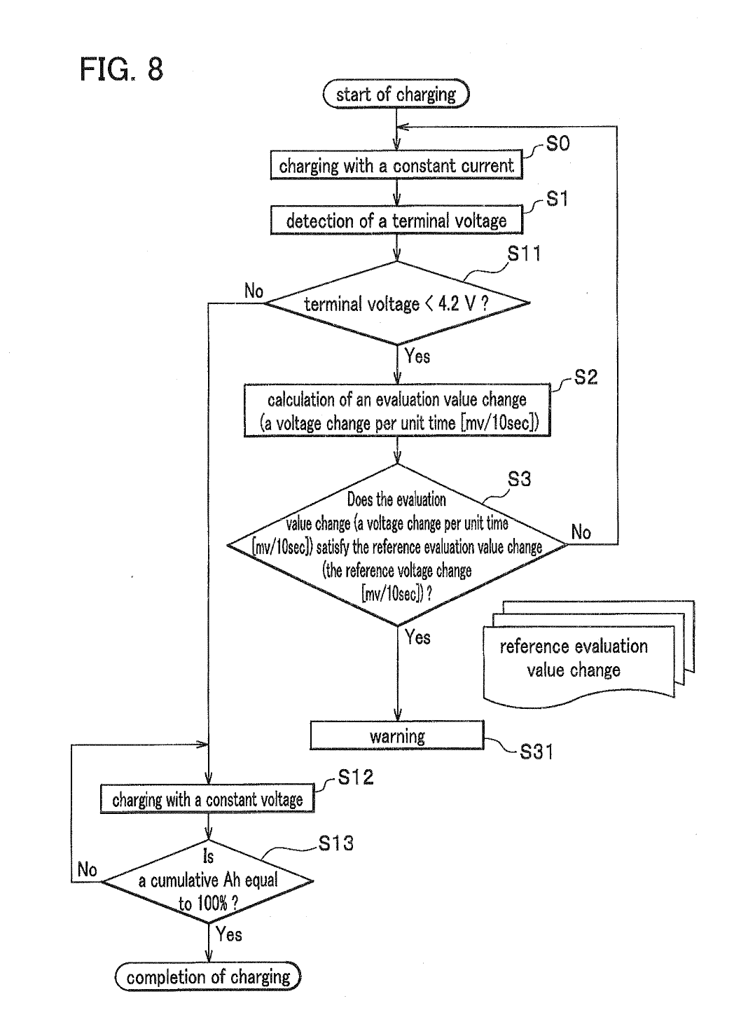

Here, by referring to FIG. 8, an embodiment of a specific operation in each of the steps is described. At first, a lithium ion secondary battery 2 (battery unit 20) is connected to a charger 10 (both are shown in FIG. 1) to start charging with a constant current (Step S0). Then the voltage detection step (Step S1) is performed where the voltage detection unit 4 detects the terminal voltage of battery unit 20. In the case that the battery unit 20 uses a plurality of lithium ion secondary batteries 2, terminal voltage of the battery unit 20 may be detected as a whole one value entity of the battery unit 20. Alternatively, all the terminal voltages of the lithium ion secondary batteries 2 may be detected individually as well. Further, charging with a constant current may be conducted at the current value, for example, at 50 A that can make the charging completed in an hour.

Next to the voltage detection step (Step S1) where the terminal voltage of the battery unit 20 is detected, Step (S11) is performed to determine whether the detected terminal voltage is lower than 4.2 V (the infection point described above) or not. Consequently, when the terminal voltage is not lower than 4.2 V (“No” in Step (S11)), Step (S12) is performed to start charging with a constant voltage. Then, Step (S13) is performed to determine whether the cumulative ampere-hour (Ah) by charging with a constant voltage has reached 100% or not . When the cumulative Ah equals does not reach 100% (“No” in Step (S13)) Step (S12) is performed to keep charging with a constant voltage again as before. When the cumulative Ah is equal to 100% (“Yes” in Step (S13)), charging is completed. Further, during charging with a constant voltage, current value may be controlled, for example, to be 50 A at the time when the terminal voltage reached 4.2 V, and to be decreased gradually after the charging is completed.

That the terminal voltage calculated in Step (S11) is lower than 4.2 V (“Yes” in Step (S11)) means a possibility of appearance of the effect of the charge curve of graphite (See FIG. 4). Accordingly, while keeping the detection of the terminal voltage, the calculation step for an evaluation value change (Step S2) is performed to calculate the evaluation value change (terminal voltage change per unit time [mV/10 sec]) using calculation unit for an evaluation value change 5. Then, the calculated evaluation value change is stored into the storage unit for an evaluation value change 51 and inputted into the control unit 3.

Next, the determination step (Step S3) is performed at the control unit 3. The determination on whether the evaluation value change meets the requirements of the reference evaluation value change or not is made by comparing the evaluation value change (voltage change per unit time [mV/10 sec]) calculated in the calculation step for an evaluation value change (Step S2) with a reference evaluation value change under the predetermined condition (the reference voltage change per unit time [mV/10 sec]).

When the evaluation value change does not meet the requirements of the reference evaluation value change (“No” in determination step (Step S3)), Step (S0) is performed to charge with a constant current again. On the other hand, when the evaluation value change meets the requirements of the reference evaluation value change (“Yes” in determination step (Step S3)), the lithium ion secondary battery 2 is determined to be deteriorated. Therefore, in this case, Step (S31) is performed to output the warning of deterioration of the battery unit 20 (lithium ion secondary battery 2).

In this way, according to one embodiment of the monitoring method for a lithium ion secondary battery, after detecting the terminal voltage, by operating each step described above, that is, by calculating voltage change per unit time [mV/10 sec] as the evaluation value change, comparing the evaluation value change with a reference evaluation value change under the predetermined condition, whether the battery unit 20 (lithium ion secondary battery 2) is deteriorated or not is determined.

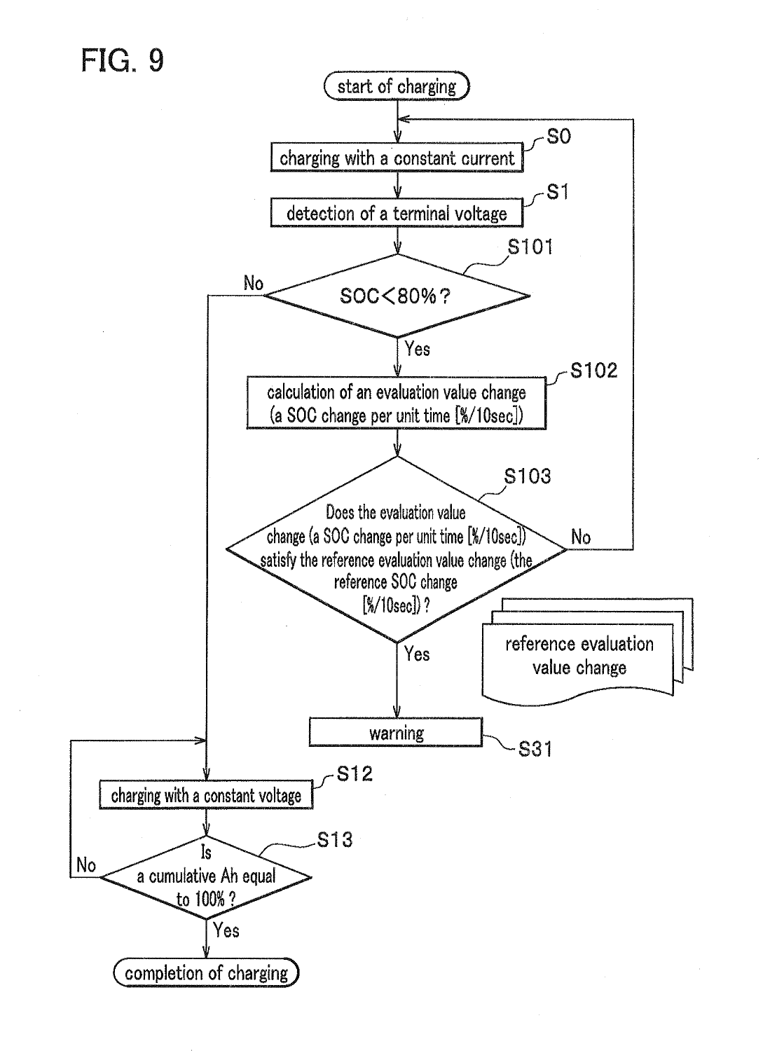

On the other hand, in the monitoring method for a lithium ion secondary battery according to the present invention, in accordance with such as another embodiment of the specific operation shown in FIG. 9, after detecting the terminal voltage at the voltage detection step (Step S1), Step (S101) is performed to calculate an SOC from this detected terminal voltage. Determination may be made whether the SOC is lower than 80% or not. When the SOC is not lower than 80%, Step (S12) is performed to charge with a constant voltage. When the cumulative Ah is equal to 100% (“Yes” in Step (S13)), charging is completed. While the cumulative Ah is not equal to 100% (“No” in Step (S13)), then Step (S12) is performed to keep charging with a constant voltage again as before.

That the SOC calculated in Step (S101) is lower than 80% (“Yes” in Step (S101)) means a possibility of appearance of the effect of the charge curve of graphite (See FIG. 4) is similar to the above described. Accordingly, while keeping the detection of the terminal voltage, the calculation step for an evaluation value change (Step S102) is performed to calculate the evaluation value change (an SOC change per unit time [%/10 sec]) using calculation unit for an evaluation value change 5. Then, the calculated evaluation value change is stored into the storage unit for an evaluation value change 51 and inputted into the control unit 3.

Next, the determination step (Step S103) is performed at the control unit 3. The determination on whether the evaluation value change meets the requirements of the reference evaluation value change or not is made by comparing the evaluation value change (an SOC change per unit time [%/10 sec]) calculated in the calculation step for an evaluation value change (Step S102) with a reference evaluation value change under the predetermined condition (the reference SOC change per unit time [%/10 sec]).

When the evaluation value change does not meet the requirement of the reference evaluation value change (“No” in determination step (Step S3)), Step (S0) is performed to charge with a constant current again. On the other hand, when the evaluation value change meets the requirement of the reference evaluation value change (“Yes” in determination step (Step S3)), the lithium ion secondary battery 2 is determined to be deteriorated. Therefore, in this case, Step (S31) is performed to output the warning of deterioration of the battery unit 20 (lithium ion secondary battery 2).

In this way, according to another embodiment of the monitoring method for a lithium ion secondary battery, after detecting the terminal voltage and calculating an SOC, by operating each step described above, that is, by calculating an SOC change per unit time [%/10 sec] as the evaluation value change, comparing the evaluation value change with a reference evaluation value change under the predetermined condition, whether the battery unit 20 (lithium ion secondary battery 2) is deteriorated or not is determined.

The monitoring system for a lithium ion secondary battery and the monitoring method for a lithium ion secondary battery according to the present invention has been shown and described in detail above with the preferred embodiments, and it is understood that this invention is not to be unduly limited to the illustrative embodiments set forth herein, and various modifications and alterations of this invention may be made without departing from the spirit and scope of the invention.

For example, FIG. 8 shows the specific operation in the monitoring method for a lithium ion secondary battery according to the present invention, describing that after voltage detection step (Step S1), Step (S11) is operated. However, Step (S11) may be operated before voltage detection step (Step S0). Similarly, FIG. 9 shows that after voltage detection step (Step S1), Step (S101) is operated. However, Step (S101) may be operated before voltage detection step (Step S0).

### REFERENCE SIGNS LIST

1 monitoring system for A lithium ion secondary battery

2 lithium ion secondary battery

20 battery unit

21 cathode

22 cathode tab

23 cathode current collecting plate

24 cathode lead

25 anode

26 anode tab

27 anode current collecting plate

28 separator

29 power generation element

3 control Unit

4 voltage detection unit

5 calculation unit for an evaluation value change

51 storage unit for an evaluation value change

6 storage unit for a reference evaluation value change

10 battery charger

S1 voltage detection step

S2 storage step for an evaluation value change

S3 determination step

What is claimed is:

1. A monitoring system for a lithium ion secondary battery that comprises: a cathode including a lithium transition metal composite oxide; an anode including non-graphitizable carbon and graphite as anode active materials which absorb and release lithium; and an electrolyte which is filled between the cathode and the anode containing at least one lithium salt, the monitoring system comprising:
a control unit for monitoring a state of the lithium ion secondary battery;
a voltage detection unit which detects a terminal voltage of a battery unit of one or a plurality of the lithium ion secondary battery/batteries;
a calculation unit for an evaluation value change which calculates a voltage change per unit time using the terminal voltage detected by the voltage detection unit as the evaluation value change, or calculates an SOC using the terminal voltage detected by the voltage detection unit and calculates an SOC change per unit time as the evaluation value change; and
a determination unit of the control unit which determines that the battery unit is deteriorated by comparing the evaluation value change calculated above with a reference evaluation value change under the predetermined condition.

2. The monitoring system according to claim 1, wherein the predetermined condition is at least one of a member from selected from a current value during charging, a temperature during charging, a voltage value during charging and an SOC.

3. The monitoring system according to claim 1, wherein the battery unit is determined to be deteriorated by the determination unit:
if the evaluation value change is within a first specific range of the reference evaluation value change for the battery unit being deteriorated;
if the evaluation value change is outside of a second specific range of the reference evaluation value change for the battery unit being undeteriorated;
if the evaluation value change does not reach a first specific value of the reference evaluation value change for the battery unit being undeteriorated; or
if the evaluation value change reaches a second specific value of the reference evaluation value change for the battery unit being deteriorated.

4. The monitoring system according to claim 2, wherein the battery unit is determined to be deteriorated by the determination unit:
if the evaluation value change is within a first specific range of the reference evaluation value change for the battery unit being deteriorated;
if the evaluation value change is outside of a second specific range of the reference evaluation value change for the battery unit being undeteriorated;
if the evaluation value change does not reach a first specific value of the reference evaluation value change for the battery unit being undeteriorated; or
if the evaluation value change reaches a second specific value of the reference evaluation value change for the battery unit being deteriorated.

5. A monitoring method for a lithium ion secondary battery using a monitoring system for a lithium ion secondary battery that comprises: a cathode including a lithium transition metal composite oxide; an anode including non-graphitizable carbon and graphite as anode active materials which absorb and release lithium; and an electrolyte which is filled between the cathode and the anode including at least one lithium salt, wherein the monitoring method comprising:
a control unit for monitoring a state of the lithium ion secondary battery;
a voltage detection step of detecting terminal voltage of a battery unit of one or a plurality of the lithium ion secondary battery/batteries;
a calculation step for an evaluation value change of calculating voltage change per unit time using the terminal voltage detected in the voltage detecting step as the evaluation value change, or calculating an SOC using the terminal voltage detected in the voltage detecting step and calculating an SOC change per unit time as the evaluation value change; and
a determination step at the control unit of determinating whether the battery unit is deteriorated by comparing the evaluation value change calculated in the calculation step for an evaluation value change with a reference evaluation value change under the predetermined condition.

6. The monitoring method according to claim 5, wherein the predetermined condition is at least one of a member from selected from a current value during charging, a temperature during charging, a voltage value during charging and an SOC.

7. The monitoring method according to claim 5, wherein in the determination step at the control unit, the battery unit is determined to be deteriorated by the determination unit:
if the evaluation value change is within a first specific range of the reference evaluation value change for the battery unit being deteriorated;
if the evaluation value change is outside of a second specific range of the reference evaluation value change for the battery unit being undeteriorated;
if the evaluation value change does not reach a first specific value of the reference evaluation value change for the battery unit being undeteriorated; or
if the evaluation value change reaches a second specific value of the reference evaluation value change for the battery unit being deteriorated.

8. The monitoring method according to claim 6, wherein in the determination step at the control unit, the battery unit is determined to be deteriorated by the determination unit:
if the evaluation value change is within a first specific range of the reference evaluation value change for the battery unit being deteriorated;
if the evaluation value change is outside of a second specific range of the reference evaluation value change for the battery unit being undeteriorated;
if the evaluation value change does not reach a first specific value of the reference evaluation value change for the battery unit being undeteriorated; or
if the evaluation value change reaches a second specific value of the reference evaluation value change for the battery unit being deteriorated.
